(19) United States
(12) Patent Application Publication
(10) Pub. No.: US 2012/0211773 A1
(43) Pub. Date: Aug. 23, 2012

(54) LIGHT-EMITTING DEVICES COMPRISING NON-LINEAR ELECTRICALLY PROTECTIVE MATERIAL

(76) Inventors: Robert Fleming, San Jose, CA (US); Daniel Vasquez, Mountain View, CA (US); Michael Glickman, San Jose, CA (US)

(21) Appl. No.: 13/359,410

(22) Filed: Jan. 26, 2012

Related U.S. Application Data
(63) Continuation-in-part of application No. 12/832,033, filed on Jul. 7, 2010.
Application No. 12/832,033 is a continuation of application No. 11/562,289, filed on Nov. 21, 2006, now Pat. No. 7,825,491.
Application No. 11/562,289 is a continuation-in-part of application No. 12/832,022, filed on Jul. 7, 2010.
Application No. 12/832,022 is a continuation of application No. 11/562,289, filed on Nov. 21, 2006, now Pat. No. 7,825,491.
(60) Provisional application No. 61/438,121, filed on Jan. 31, 2011.
(60) Provisional application No. 60/740,961, filed on Nov. 30, 2005.
(60) Provisional application No. 60/739,725, filed on Nov. 22, 2005.
(60) Provisional application No. 60/740,961, filed on Nov. 30, 2005.
(60) Provisional application No. 60/739,725, filed on Nov. 22, 2005.

(51) Int. Cl. H01L 33/08

(52) U.S. Cl. 257/88; 257/E33.055

(57) ABSTRACT

A circuit comprising an array of light emitting diodes (LEDs), and a layer of VSD material positioned to contact an input and an output of each LED in the array of LEDs, so as to protect each LED from both a forward surge and a reverse surge of voltage on the array of LEDs. The layer of VSD material is able to switch into a carrying current state in response to either of the forward or reverse surge exceeding a characteristic voltage level (V_{CL}) of the VSD material.

### RELATED APPLICATIONS

This application claims benefit of priority to Provisional U.S. Patent Application No. 61/438,121, filed on Jan. 31, 2011; the aforementioned application being hereby incorporated by reference in its entirety.

This application is a continuation-in-part of U.S. patent application Ser. No. 12/832,033, filed on Jul. 7, 2010, which is a continuation of U.S. application Ser. No. 11/562,289, filed Nov. 21, 2006 and issued as U.S. Pat. No. 7,825,491 on Nov. 2, 2010, which claims benefit of priority to (i) U.S. Provisional Application No. 60/740,961, filed Nov. 30, 2005, and (ii) U.S. Provisional Application No. 60/739,725, filed Nov. 22, 2005; all of the aforementioned applications being hereby incorporated by reference in their entirety.

This application is a continuation-in-part of U.S. patent application Ser. No. 12/832,022, filed on Jul. 7, 2010, which is a continuation of U.S. application Ser. No. 11/562,289, filed Nov. 21, 2006 and issued as U.S. Pat. No. 7,825,491 on Nov. 2, 2010, which claims benefit of priority to (i) U.S. Provisional Application No. 60/740,961, filed Nov. 30, 2005, and (ii) U.S. Provisional Application No. 60/739,725, filed Nov. 22, 2005; all of the aforementioned applications being hereby incorporated by reference in their entirety.

### FIELD OF THE INVENTION

This application pertains to light-emitting devices comprising non-linear electrically protective material.

### BACKGROUND

Traditional lighting mechanisms, such as incandescent light-bulbs, are being replaced with more efficient and powerful lighting mechanisms, such as LEDs and OLEDs. While newer lighting mechanisms offer many advantages, they are also more expensive, difficult to make, and often incorporate use of exotic materials. Furthermore, while such new devices may have relatively longer life-spans than more traditional lighting mechanisms, LEDs and OLEDs can fail when exposed to transient electrical conditions. In particular, both organic and inorganic light emitting devices, including the semiconductor chips and polymers used in these devices, are highly susceptible to Electrostatic Discharge (ESD) and other voltage transients such as electrical over-stress (EOS) and electromagnetic pulses (EMP). These devises are historically protected with zener diodes or discrete solid state or polymer surge suppressors.

### BRIEF DESCRIPTION OF THE DRAWINGS

FIG. 1 is a schematic illustration of a circuit with an array of LEDs, configured to incorporate VSD material and an ESD plane, according to an embodiment.

FIG. 2A and FIG. 2B include a circuit that includes an LED array, according to one or more embodiments.

FIG. 3A and FIG. 3B further illustrate a circuit configured with an array of LEDs, according to one or more embodiments.

FIG. 4A is a top-view diagram of a section of a circuit implemented on a double layer PCB board on an electrical insulating substrate, from point C to C′, under an embodiment.

FIG. 4B is a cross-section diagram of the circuit from point C to C′

FIG. 4C illustrates an embodiment in which a circuit with LEDs is implemented on a PCB having a metal core, according to an embodiment.

FIG. 5A illustrates an LED that is either a singular component, or part of an array of LEDs, under an embodiment.

FIG. 5B illustrates a circuit that aligns LEDs in series and utilizes a driven voltage node off of an ESD plane, in accordance with an embodiment.

FIG. 6 is a schematic of a circuit with an array of LEDs, configured to incorporate VSD material, according to embodiments.

FIG. 7 is a diagram of a circuit including an array of LEDs, configured to incorporate VSD material, according to another embodiment.

### DETAILED DESCRIPTION

Embodiments described herein pertain to light-emitting devices that utilize electrically protective material. Specifically, embodiments incorporate devices and protective mechanisms into a lighting device, including those that comprise LEDs, or an array of LEDs. Specific examples of such lighting devices include, for example, LED lighting modules and LED display modules. More specific examples include light sources for illumination (e.g., illuminate space for humans), display screens for computers, and televisions.

In particular, embodiments described herein provide for the use of a voltage switchable dielectric (VSD) material that is used as part of a circuit designed for light-emitting devices, such as LEDs and OLEDs. In variations, the VSD material can be provided as part of the packaging, and/or integrated or combined with electrical components and elements of such circuit. As provided with one or more embodiments, the integration of VSD material protects the light-emitting devices on the circuit from voltage transient electrical events such as electrostatic discharge (ESD) and electrical overstress (EOS). In some implementations, the VSD material can also protect the device from moisture, impact and other electrical or mechanical threats. Moreover, as with one or more embodiments, the integration of VSD material acts as a conduit for heat dissipation generated by the light-emitting devices on the circuit.

Embodiments also include an apparatus design and technique for safeguarding lighting mechanisms (including LEDs and OLEDs) against ESD events. In particular, one or more embodiments provide for the use of VSD material to shield an LED or OLED against ESD events.

Examples of light-emitting devices that are applicable to embodiments described herein include LEDs and OLEDs, although embodiments described have applicability to other forms of light emitting devices, as well as sensitive electrical components that may have varying forward and reverse breakdown voltages.

Examples of such electrically protective material includes varistors and voltage switchable dielectric (VSD) material. In the absence of a transient electrical event, the protective material is non-conductive, and the two electrodes are not separated. When a transient electrical event occurs, the protective material switches, so that the two electrodes are electrically connected. The protective material may be provided as part of the gap structure in order to enable, for example, the formation of grounding paths when electrical events such as ESD occur.

A VSD material in accordance with various embodiments described herein is a material that exhibits nonlinear resistance as a function of voltage. While a VSD material exhibits nonlinear resistance, not all materials that exhibit nonlinear resistance are VSD materials. For example, a material for which resistance changes as a function of temperature but does not substantially change as a function of voltage would not be construed as a VSD material for purposes of embodiments of the present invention. In various embodiments, VSD materials exhibit nonlinear resistance variation as a function of voltage and additional operating parameters such as current, energy field density, light or other electromagnetic radiation input, and/or other similar parameters.

The variation of the resistance as a function of voltage exhibited by a VSD material includes a transition from a state of high resistance to a state of low resistance. This transition occurs at about a specific voltage value, which may be variously referred to as a “characteristic voltage,” “characteristic voltage level,” “switching voltage,” or “switching voltage level.” The characteristic voltage may differ for various formulations of VSD material, but is relatively stable for a given formulation. The characteristic voltage for a particular formulation may be a function of voltage coupled with additional parameters such as temperature and/or incident electromagnetic energy at various wavelengths including optical, infrared, UV, or microwave.

For a given VSD material composition, the characteristic voltage may be defined in terms of a corresponding “characteristic electric field” or “characteristic field” expressed in terms of voltage per unit of length (e.g., Volts per mil (V/mil), Volts per micrometer (V/um), etc.).

Unless otherwise expressly indicated, the term “structure of VSD material,” “VSD material structure” or “VSDM structure” is intended to refer to any volume of VSD material with specific physical dimensions that can perform an electrical switching function. Examples of a structure of VSD material include a layer of VSD material (whether disposed on a substrate or cured as a stand-alone layer), a volume of VSD material bounded between two or more electrodes, a volume of VSD material bounded by two or more insulative or semiconductor structures, or any other element or configuration of VSD material that can switch between substantially nonconductive and substantially conductive states in response to a sufficiently large voltage variation.

In one implementation, a VSD material structure may be produced by bounding a volume of a first VSD material with a first characteristic voltage between two other volumes of VSD materials with characteristic voltages that differ from the first characteristic voltage (the characteristic voltages of the two other volumes of VSD material may or may not be equal to each other).

In one implementation, a VSD material structure may be produced by bounding a volume of a VSD material with a first characteristic voltage between (a) a volume of VSD material with a different characteristic voltage, and (b) one or more electrodes, insulative structures, and/or semiconductor structures.

An example of a VSD material structure is a layer of VSD material disposed on a copper foil (but excluding the copper foil). A compound formation that comprises both the layer of VSD material and the copper foil may be denoted a “formation of VSDM.” More complex formations of VSDM are discussed below.

Another example of a VSD material structure is a coating, sheet, or other layout of VSD material, disposed as a horizontal layer in a PCB and bounded between two adjacent horizontal layers of the PCB (i.e., a horizontal layer above the VSD material structure, and a horizontal layer below the VSD material structure). A compound formation that comprises both this VSD material structure and the bounding two adjacent horizontal layers would be an example of a formation of VSDM.

Another example of a VSD material structure is a volume of VSD material disposed in a horizontal layer within a PCB and bounded between four structures disposed within the same horizontal layer of the PCB (e.g., four etched channels that delineate a rectangular VSD material structure) and between two electrodes disposed in the two adjacent horizontal layers (e.g., a conductive layer above and an insulative layer below). A compound formation that comprises both this VSD material structure and the bounding four structures and two electrodes would be an example of a formation of VSDM.

For a structure of VSD material with a known distance between two points where a voltage is applied (e.g., when a voltage is applied across the thickness of a layer of VSD material or across another gap of a VSD material structure), the characteristic voltage may be defined as specific voltage value (e.g., the characteristic voltage for this VSD material structure may be specified as a particular value in Volts).

Consequently, the characteristic voltage of a VSD material structure may be defined in terms of a characteristic electric field expressed as a voltage value per unit length, or as a characteristic voltage expressed as a specific voltage value when the VSD material is considered as a specific volume with certain known dimensional characteristics (e.g., a VSD material structure with a specific thickness across which voltage switching may occur). In various contexts, the descriptions in this patent may refer to characteristic fields or characteristic voltages of VSD materials in connection with various embodiments, and in each case the corresponding characteristic fields (in terms of Volts per unit length) or characteristic voltages (in terms of Volts) may be obtained through an appropriate conversion by taking into account the dimensional characteristics of the respective structures of VSD material. For example, for a uniform characteristic electric field produced within a VSD material structure, the characteristic voltage of that VSD material structure may be obtained by multiplying the characteristic field of that VSD material (in V/mil) by the corresponding gap across which switching will take place (in mils)). In a more general sense, for a non-uniform characteristic electric field produced within a VSD material structure, the characteristic voltage of that VSD material structure may be obtained by integrating the characteristic field of that VSD material throughout the gap across which switching will take place. In some embodiments, for some formulations of VSD materials and physical characteristics of the gaps across which switching may take place, the characteristic voltage of the VSD material across such gaps may not be directly or linearly correlated with the size of the respective gaps (e.g., in such embodiments, the respective characteristic voltages may be evaluated through direct measurements or through more complex simulations or approximations).

In general, the characteristic voltage of a VSD material structure may be a function of the amount, cross-sectional area, volume, depth, thickness, width and/or length of the VSD material structure that is disposed between the two points where the voltage is applied, and possibly also a function of the relative shape, geometry, density variation, and other analogous variables relating to the VSD material structure.

A VSD material is substantially non-conductive (i.e., substantially insulative) at voltages below the respective characteristic voltage level, in which case it behaves substantially as an insulator or dielectric. This state may be referred to as a substantially nonconductive or insulative state. Voltages below the characteristic voltage level of a VSD material may be referred to as low voltages (at least relative to voltages above the characteristic voltage level). In such operating regimes below the characteristic voltage level, a VSD material provided in embodiments of the current invention may also be construed as having attributes of a semiconductor, similar to semiconductor materials that are suitable to serve as substrates in semiconductor manufacturing processes. A VSD material in accordance with various embodiments may behave substantially as an insulator for both positive and negative voltages when the magnitude of the voltage is below the characteristic voltage level.

At voltages higher than its characteristic voltage level, a VSD material, in accordance with various embodiments of the present invention, behaves substantially as a conductor by having substantially low electric resistance, or relatively low resistance. This may be referred to as a substantially conductive state. Voltage above the characteristic voltage level may be referred to as high voltage. The VSD material is conductive or substantially conductive for both positive and negative voltages when the magnitude of the voltage is above the characteristic voltage level. The characteristic voltage may be either positive or negative, depending on the polarity of the voltage being applied. When a VSD material becomes substantially conductive in response to a voltage that exceeds its characteristic voltage, the VSD material could be said to “switch on.” When a VSD material becomes substantially non-conductive after removing a voltage that exceeds its characteristic voltage, the VSD material could be said to “switch off.” When a VSD material switches on or off, the VSD material could be simply said to “switch.”

In an ideal model, the operation of a VSD material provided in various embodiments of the present invention is approximated as having infinite resistance at voltages below the characteristic voltage, and zero resistance at voltages above the characteristic voltage. In normal operating conditions, however, such VSD materials typically have high, but finite resistance at voltages below the characteristic voltage, and low, but nonzero resistance at voltages above the characteristic voltage. As an example, for a particular VSD material, the ratio of the resistance at low voltage to the resistance at high voltage may be expected to approach a large value (e.g., in the range of 10̂3, 10̂6, 10̂9, 10̂12, or higher). In an ideal model, this ratio may be approximated as infinite, or otherwise very high.

Still further, the VSD material provided in some embodiments exhibits high repeatability (i.e., reversibility) in its operation in both the low voltage regimes and the high voltage regimes. In some embodiments, the VSD material behaves substantially as an insulator or dielectric (i.e., is substantially nonconductive and exhibits a very or substantially very electric resistance) at voltages below the characteristic voltage level. The VSD material then switches to become substantially conductive when operated at voltages above the characteristic voltage level, then becomes again substantially an insulator or dielectric at voltages below the characteristic voltage. In some embodiments, the VSD material can alternate between these two operational states repeatedly if the input voltage levels transition between voltages below the characteristic voltage and above the characteristic voltage. While transitioning between these two operational states, a VSD material may experience a certain level of hysteresis, which may after, to a certain extent, the characteristic voltage level, the switching response time, or other operational characteristics of the VSD material.

The transition between the first (lower) voltage regime, when the VSD material is substantially insulative, and the second (higher) voltage regime when the VSD material is substantially conductive, in accordance with embodiments of the current invention, is substantially predictable and is expected to be generally confined to a limited envelope of signal amplitudes and a limited range of switching times. In an ideal model, the time that it takes a VSD material to transition from a state of substantial insulation to a state of substantial conductance in response to an input step function signal that rises above the characteristic voltage can be assumed to be zero. The reverse transition may also be approximated to be substantially fast. Under normal operating conditions, however, both of these transition times for VSD materials are non-zero. In general, such transition times are small, and are preferably as small as possible (e.g., in the range of about 10̂-6 seconds, 10̂-9 seconds, 10̂-12 seconds, or smaller). Further details of the formulations and characteristics of VSD materials are disclosed in U.S. Pat. No. 7,872,251, issued on Jan. 18, 2011 to Kosowsky, et al., and titled “Formulations for Voltage Switchable Dielectric Material Having a Stepped Voltage Response and Methods for Making the Same,” which is hereby incorporated by reference in its entirety.

When in a substantially conductive state, a VSD material in accordance with various embodiments may direct an electrical signal to ground or to another predetermined point within the respective circuit, substrate or electronic device to protect an electronic component. In various embodiments, the predetermined point is a ground, virtual ground, shield, safety ground, and the like. Examples of electronic components that may be operated with and/or protected by VSD materials in accordance with various embodiments of the present invention include (a) circuit element, circuit structure, surface mounted electric component (e.g., resistors, capacitors, inductors), PCB or other circuit board, electronic device, electronic subsystem, electronic system, (b) any other electric, magnetic, micro-electromechanical structure (MEMS) or similar element, structure, component, system and/or device, (c) any other unit that processes or transmits data and operates using electric signals or may be damaged by electric signals, and (d) any combination of the foregoing identified in (a), (b) and/or (c) above.

In general, a VSD material may have a limited ability to conduct current or otherwise operate in the presence of high signal voltages, current intensities, and energy or power levels before being damaged, possibly irreversibly damaged. Additionally, a VSD material may also be damaged if an electric signal that is normally within operating specifications persists for too long (e.g., the VSD material may heat up while conducting such signals and eventually break down). For example, a VSD material may be able to function normally when exposed to an input signal with a voltage level of 10 KV that lasts less than 100 nanoseconds, but may be damaged if that signal continues to be applied for more than a few milliseconds. The ability of a VSD material to tolerate high levels of voltage, current, power or energy before becoming damaged may depend on various factors, such as the particular composition of the VSD material, the specific characteristics of a corresponding VSD material structure (e.g., a VSD material structure with larger physical dimensions may be able to conduct higher current densities), the corresponding circuit architecture, the presence of other ESD protective components, and the characteristics of the device in which the VSD material is incorporated.

VSD materials in accordance with various embodiments are polymer composites, and may include particulate materials such as metals, semiconductors, ceramics, and the like. Examples of various compositions of VSD materials that may be used in accordance with various embodiments are described in, for example, U.S. patent application Ser. No. 12/953,309 filed on Nov. 23, 2010 and titled “Formulations for Voltage Switchable Dielectric Materials Having a Stepped Voltage Response and Methods for Making the Same,”, U.S. patent application Ser. No. 12/832,040 filed on Jul. 7, 2010 and titled “Light-Emitting Diode Device For Voltage Switchable Dielectric Material Having High Aspect Ratio Particles,” and U.S. patent application Ser. No. 12/717,102 filed on Mar. 3, 2010 and titled “Voltage Switchable Dielectric Material Having High Aspect Ratio Particles,” and U.S. Pat. No. 7,981,325 issued on Jul. 19, 2011 and titled “Electronic Device For Voltage Switchable Dielectric Material Having High Aspect Ratio Particles.”

VSD materials in accordance with various embodiments may include a matrix material and one or more types of organic and/or inorganic particles dispersed within the matrix material.

Examples of matrix materials incorporated in VSD materials, in accordance with various embodiments, may include organic polymers, such as silicone polymer, phenolic resin, epoxy (e.g., EPON Resin 828, a difunctional bisphenol A/epichlorohydrin derived liquid epoxy resin), polyurethane, poly(meth)acrylate, polyamide, polyester, polycarbonate, polyacrylamides, polyimide, polyethylene, polypropylene, polyphenylene oxide, polysulphone, ceramer (a solgel/polymer composite), and polyphenylene sulfone. Other examples of such matrix materials include inorganic polymers, such as siloxane, and polyphosphazines.

Examples of particles incorporated in VSD materials, in accordance with various embodiments, may include conductive and/or semiconductive materials including copper, aluminum, nickel, silver, gold, titanium, stainless steel, chrome, tungsten, other metal alloys, T, Si, NiO, SiC, ZnO, BN, C (including in the form of diamond, nanotubes, and/or fullerenes), ZnS, Bi₂O₃, Fe₂O₃, CeO₂, TiO₂, AIN, and compounds of indium diselenide. In some embodiments, metal oxides such as TiO₂ can be undoped or doped, for example with WO3, where doping may include a surface coating. Such particles may have a shape ranging from spherical to highly elongated, including high aspect ratio particles, including carbon nanotubes (single walled and/or mufti-walled), fullerenes, metal nanorods, or metal nanowires. Examples of materials that form nanorods and/or nanowires include boron nitride, antimony in oxide, titanium dioxide, silver, copper, tin, and gold.

The aspect ratio of some particles incorporated in VSD materials in accordance with various embodiments may have aspect ratios in excess of 3:1, 10:1, 100:1, and 1000:1. Materials with higher aspect ratios are sometimes called “High Aspect Ratio” particles or “HAR” particles. Carbon nanotubes are examples of super HAR particles, with aspect ratios of an order of 1000:1 and more. Materials with lesser aspect ratios that may be incorporated in VSD materials in various embodiments include carbon black (L/D of any order of 10:1) particles, and carbon fiber (L/D of an order of 100:1) particles.

The particles incorporated in VSD materials, in accordance with various embodiments, may have various sizes, including some nanoscale particles characterized by a smallest dimension equal to 500 nm or smaller, or even smaller (e.g., particles for which a smallest dimension is less than 100 nm or 50 nm).

The particles incorporated in VSD materials in accordance with various embodiments may include organic material. Incorporating organic materials within a VSD material may provide to the VSD material improved coefficients of thermal expansion and thermal conductivity, better dielectric constant, enhanced fracture toughness, better compression strength, and improved ability to adhere to metals. Examples of organic semiconductors that may be incorporated in VSD materials in various embodiments include forms of carbon such as electrically semiconducting carbon nanotubes and fullerenes (e.g., C60 and C70). Fullerenes and nanotubes can be modified, in some embodiments, to be functionalized to include a covalently bonded chemical group or moiety. Other examples of organic semiconductors that may be incorporated in VSD materials in various embodiments include poly-3-hexylthiophene, polythiophene, polyacteylene, poly(3,4-ethylenedioxythiophene), poly(styrenesulfonate), pentacene, (8-hydroxyquinolinolato) aluminum (III), and N,N′-di-[(naphthalenyl)-N,N′diphenyl]-1,1′-biphenyl-4 and 4′-diamine [NPD]. Additionally, organic semiconductors can be derived from the monomers, oligomers, and polymers of thiophene, analine, phenylene, vinylene, fluorene, naphthalene, pyrrole, acetylene, carbazole, pyrrolidone, cyano materials, anthracene, pentacene, rubrene, perylene, and oxadizole. Some of these organic materials may be photo-active organic materials, such as polythiophene.

In reference to distribution of particles within a VSD material polymeric composition, distributing particles “substantially uniformly” means that on the average the respective particles are distributed uniformly and/or randomly within the material, but it is certainly possible that in limited subportions of the polymeric composition nonuniform and/or non-random agglomerations of such particles may occur. Indeed, even after extensive mixing, there will normally be a nonzero statistical probability with which such agglomerations of particles may occur within limited volumes within the VSD material, and this could happen though all phases of the VSD material, including when the VSD material is in a liquid or semi-liquid form before application to a substrate, after it is disposed on a substrate (for example through coating), and/or after it is cured (whether on a substrate or otherwise). Overall, however, when considering the whole quantity of VSD material (or a sufficiently large subportion of such VSD material) the respective particles may be deemed to be distributed uniformly and/or randomly within the mixture, and in modeling the behavior of the respective VSD material, the particles may be modeled as being distributed uniformly and/or randomly.

In various embodiments, the characteristic voltage of a VSD material structure disposed between two electrodes contacting the VSD material decreases as the distance between the electrodes decreases. The distance between the electrodes across which the VSD material may switch between substantially conductive and substantially nonconductive states in response to voltage variations that are sufficiently large could be denoted a “thickness,” “effective thickness,” “gap,” “switching gap,” or “effective gap.” The effective gap for a VSD material structure could be considered to be horizontal if the two electrodes are disposed in a substantially horizontal plane, or could be considered to be vertical if the two electrodes are disposed in different vertical planes and/or if the voltage switching takes place predominantly in a vertical direction.

In general, a “substrate device” that may be protected by a VSDM formation against ESD or other overvoltage events, or into which a VSDM formation may be incorporated, means any solid medium to which a substance or structure is applied or otherwise attached. For simplicity, a substrate device may sometimes be denoted a “substrate.”

In some embodiments, the term substrate may refer to a slice of semiconductor material such as silicon, metal oxide or gallium arsenide (GaAs) that serves as the foundation for the construction of components such as transistors and integrated circuits (IC s). In the manufacture of an IC, the substrate material is cut or formed into wafers, on which the individual electronic components are etched, deposited or fabricated.

In some embodiments, the term substrate may refer to a first (1st) level package. A first level package may comprise one or more materials, disposed in one or more layers. Examples of materials that may be included in a first level package include any metal, ceramic, glass, silicon, polymeric material (e.g., FR4, FR5, BT), or any combination of the foregoing. A first level package may also comprise electronic circuitry that serves as the foundation for connecting single or multiple integrated circuits (e.g., examples of such multiple integrated circuits include a die, chip or device) using an interconnecting material. Examples of such interconnecting materials include solder, metal plating, wire or tab bonding, or other interconnection materials. An interconnecting material may adhere to a metal pad patterned onto the substrate which connects the integrated circuits to the substrate. In such configurations, the interconnection between an integrated circuit and the substrate is referred to as first (1st) level interconnect, and the substrate is then commonly referred to as 1st level package, or 1st level interconnect package, or 1st level substrate package. A first level package can also be referred to as a printed wiring board (PWB) or printed circuit board (PCB). A 1st level interconnect package, in various applications, may have metal pads patterned on the top side or bottom side which are used to interconnect the 1st level package to a second (2nd) level package.

In some embodiments, the term substrate may refer to a second (2nd) level package. A second level package may have the same structure, architecture and functionality as described above for a first level package, but is disposed as a different layer in a mufti-layer stack that also includes a first layer package.

In various embodiments, examples of substrates may include a PCB, any single layer or set of multiple layers of a PCB, the package of a semiconductor device (e.g., ball grid array (BGA), a land grid array (LGA), a pin grid array), an LED substrate, an integrated circuit (IC) substrate, an interposer or any other platform that connects two or more electronic components, devices or substrates (where such connection may be vertical and/or horizontal), any other stacked packaging or die format (e.g., an interposer, a wafer-level package, a package-in-package, a system-in-package, or any other stacked combination of at least two packages, dies or substrates), or any other substrate to which a VSDM formation can be attached or within which a VSDM formation may be incorporated.

Another class of VSD material is varistors. In contrast to polymeric VSD material, varistors lack any presence of binder. As such, the varistor is non-polymeric VSD material, formed from materials such as zinc oxide, bismuth oxide, tungsten oxide, or cadmium telluride.

VSD materials, including varistors, are used to protect electrical devices from transient electrical events, such as Electrostatic Discharge (ESD) or other transient events.

According to one or more embodiments, a circuit includes use of VSD material and an ESD plane with floating voltage. Such ESD plane is not electrically connected to any other component or interconnects on the circuit, thus having floating voltage. The combined design of VSD material and the ESD plane enables VSD material to discharge surge voltage and current to the ESD plane during an ESD event, and to dissipate heat during normal operation.

Additionally, one or more embodiments provide for use of VSD material and an ESD plane with a fixed voltage to reduce the voltage potential seen by VSD material on the circuit during normal operating conditions and to minimize the voltage potential placed on the LED devices during an ESD event. The fixed voltage may be configured to be ground, one-half of supply voltage, or any other voltage a circuit designer sees fit, so that the voltage of the discharge plane does not shift due to leakage current or any other reasons. The combined design of VSD material and the ESD plane enables VSD material to discharge surge voltage and current to the ESD plane during an ESD event, and to dissipate heat during normal operation.

In one or more embodiments, use of VSD material and an ESD plane assists heat dissipation generated by the light-emitting devices on the circuit. Specifically, in one or more embodiments, the ESD plane is fabricated to form a fin pattern to increase thermal conductivity.

Furthermore, one or more embodiments provide for use of VSD material and one or more ESD planes to reduce the voltage potential seen by VSD material on the circuit during normal operating conditions and to minimize the voltage potential placed on the LED devices during an ESD event.

Still further, one or more embodiments provide for use of VSD material and one or more ESD planes with the light-emitting devices connected in series to reduce the voltage potential seen by VSD material on the circuit during normal operating conditions and to minimize the voltage potential placed on the LED devices during an ESD event.

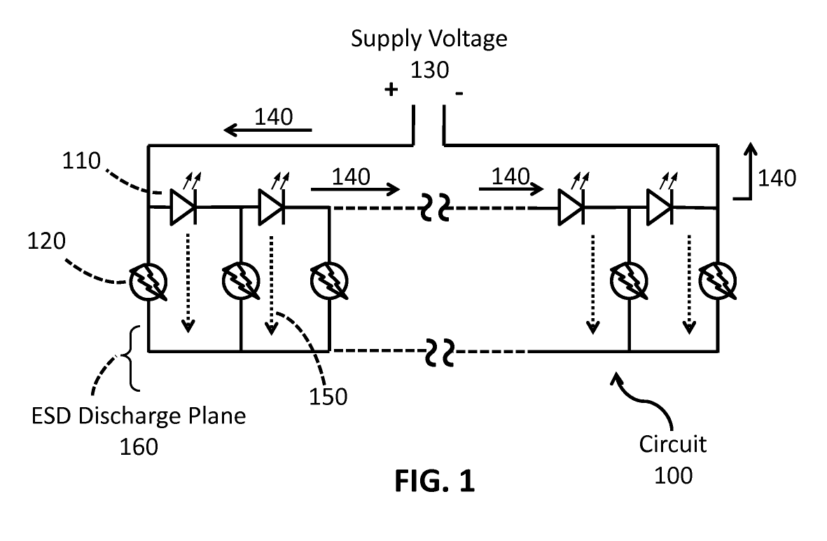

FIG. 1 is a schematic illustration of a circuit 100 with an array of LED devices 110, configured to incorporate VSD material 120 and an ESD plane 160, according to an embodiment. In an embodiment of FIG. 1, a circuit 100 having an array of LED devices 110 is configured to provide, under normal operating conditions, the LED devices 110 with a supply current 140 and supply voltage 130. When activated by the current 140, the LED devices 110 emit light that has wavelength characteristics determined by the composition of the LED devices 110. When turned on, each LED device operates at a voltage known as “forward voltage” (V_{Forward}).

In an embodiment, VSD material 120 is provided underneath or as part of a substrate or other structure that supports the semiconductor component of the LED devices 110. Under normal conditions, the substrate has substantially insulative properties (such as determined by the natural electrical resistance of the VSD material), so that the normal current and voltage supply are unimpeded. If, however, a surge (or transient) voltage is generated that exceeds the characteristic voltage level of the VSD material 120, the VSD material 120 of the substrate switches into having a lower inherent electrical resistance, so as to be substantially electrically conductive. In the substantially electrically conductive state, the VSD material 120 provides a ground path for the resulting surge current flow 150. The surge voltage that triggers the current flow 150 may be any voltage that is above a characteristic voltage level of the VSD material applied or integrated with the substrate.

In a configuration such as shown by FIG. 1, each LED 110 in the array is electrically interconnected to the VSD material 120 at both the input and output locations of each LED 110. Thus, each LED 110 is independently protected from an ESD event by the VSD material 120. Furthermore, each LED 110 can be protected in both the forward and reverse directions.

In an embodiment, an ESD plane 160 is provided as an outlet for the current flow 150 caused by the surge voltage in an ESD event. The ESD plane 160 can electrically interconnect to each LED 110 in the array that experiences a surge that exceeds the characteristic voltage level of the VSD material 120. In an embodiment, the ESD plane 160 has a configuration that, under normal operating conditions, is not electrically connected to elements of circuit 100. In such embodiment, the plane 160's voltage is floating during normal operating conditions (i.e., VSD material 120 not switched). In another embodiment, the ESD plane 160, during normal operation condition, may maintain its voltage floating at approximately one-half (½) of the supply voltage 130, but the voltage may vary due to leakage current or other factors. The ESD plane 160 is made of electrically conductive material.

The ESD plane 160 can be formed from a variety of conductive materials, and further can be shaped or physically structured to enhance its performance. Specific materials for use in ESD planes include copper, aluminum, gold, silver, or any other electrically conductive metal material common to the circuit design industry. As described with other embodiments, the ESD plane 160 can be shaped, for example, to act as a heat sink, so as to facilitate protection of the individual LEDs 110 against both electrical surges and heat.

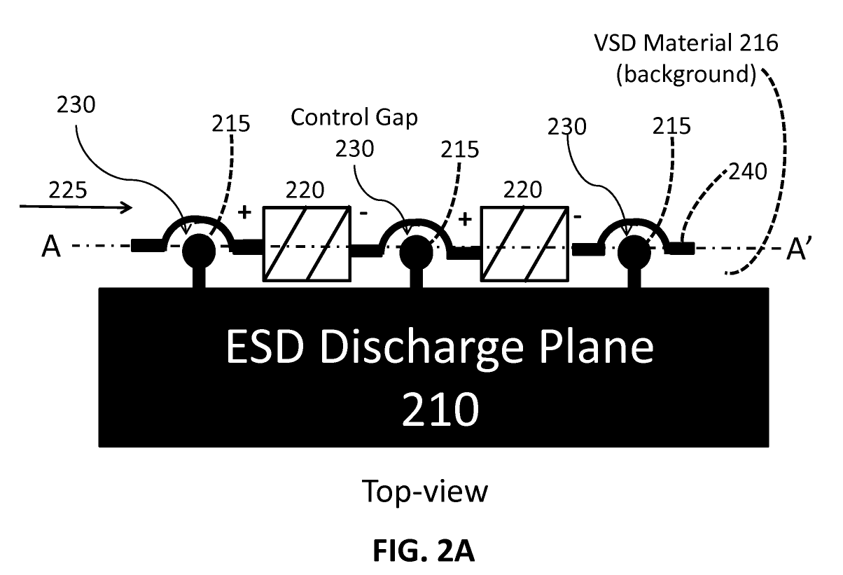

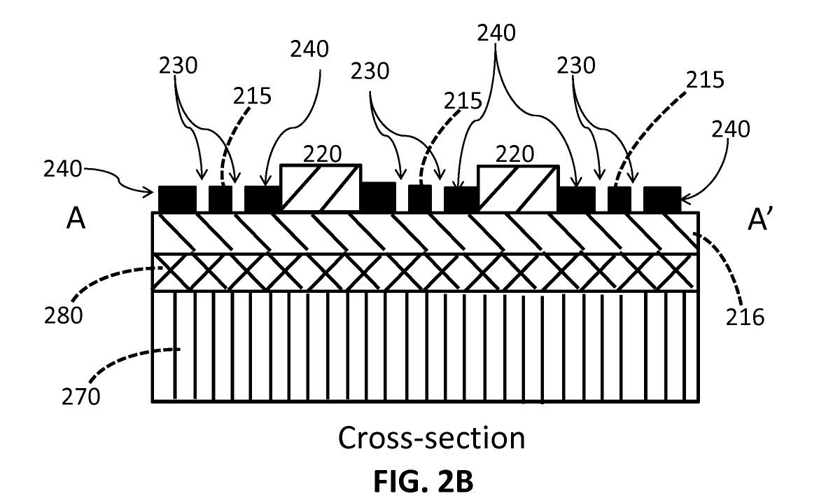

FIG. 2A and FIG. 2B include a circuit that includes an LED array, according to one or more embodiments. Shown in FIG. 2A is a top-view diagram of a section of a circuit implemented on a single layer printed circuit board (PCB) on electrical insulating substrate 270 from point A to A′. FIG. 2B is a cross-section diagram of the circuit from point A to A′. An ESD plane 210 can be seen from the top-view of the circuit. In an embodiment such as shown by FIG. 2A and FIG. 2B, the LED devices 220 are connected in series. During normal operation, a supply current 225 flows through the LED devices 220 from point A to A′ via wire 240. VSD material 216 and a control gap 230 separate the ESD plane 210 from the wire 240 so that the supply current goes to the LED devices 220 during normal operation. In one embodiment, a protruding terminal 215 is electrically connected to the ESD plane 210 and extends toward the wire 240, but is separated from the wire 240 by the control gap 230. The protruding terminal 215 can be seen as a part of the ESD plane 210 and may or may not be made of the same material.

In one embodiment, VSD material 216 is placed underneath the circuit from point A to A′ and is shown as background from the top-view. For example, the ESD plane 210 and the LEDs 220 can overlay the VSD material 216, and/or be in contact with the VSD material 216. In an ESD event, the VSD material 216 becomes electrically conductive and directs the surge current from wire 240 to the ESD plane 210 through the protruding terminal 215. This allows surge current to be diverted from passing through the LED, so that damage from the ESD event can be avoided. Furthermore, through the VSD material 216 and protruding terminals 215, the heat generated by the LED devices 220 can be dissipated to the ESD plane 210 during the circuit's operation.

More specifically, in some embodiments, the ESD plane 210 may be used in conjunction with or be formed as a thermal pad. As in any variation, the ESD plane 210 may be formed, engraved, or etched to become a shape that increases surface area to enhance thermal conductivity. For example, the ESD plane 210 can be fin patterned, have vertical edges, or be formed in concentric circles to facilitate its use as a heat sink.

In one or more embodiments, protruding terminal 215 is placed between the ESD plane 210 and the wire 240 to provide a shortest path to the ground for a surge current in ESD events, so that most of the surge current goes through the shortest path to ground instead of going through (and potentially damaging) the LED devices 220. The protruding terminal 215 can be formed into any shape that results in reduced resistance to better direct the surge current to the ESD plane 210. For example, in one embodiment, the protruding terminal 215 is designed to form a circular shape on the end that is away from the ESD plane 210. The protruding terminal 215 can be seen as a part of the ESD plane 210.

As an addition or alternative, a thermally conductive layer 280 is laid underneath the VSD material 216 to further improve the heat dissipation of the entire circuit.

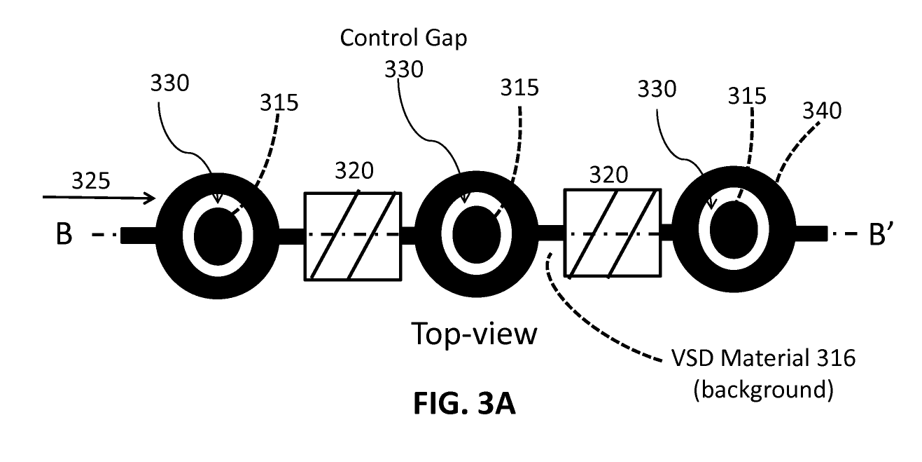

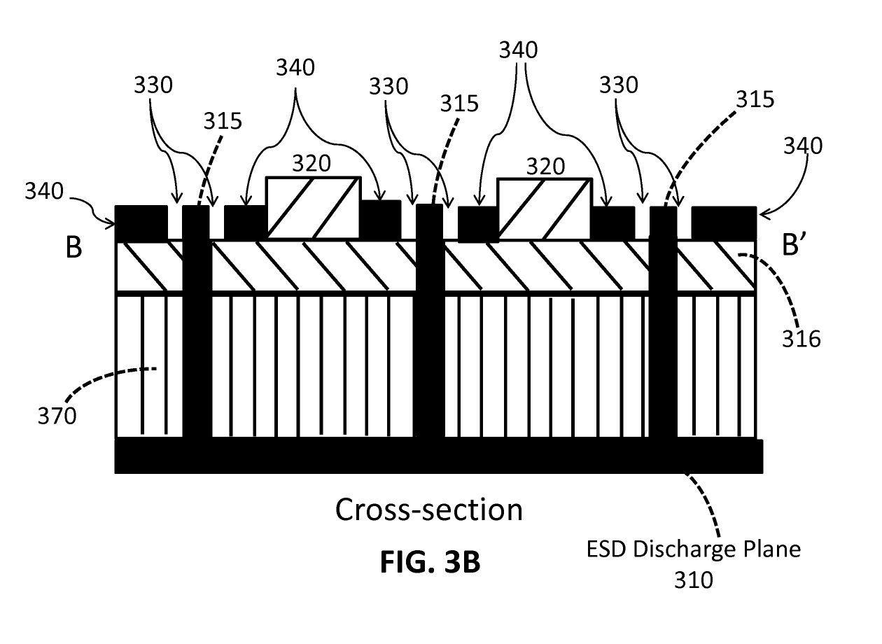

FIG. 3A and FIG. 3B further illustrate a circuit configured with an array of LED devices. Shown in FIG. 3A is a top-view diagram of a section of a circuit implemented on a double layer PCB board on electrical insulating substrate 370 from point B to B′. FIG. 3B is a cross-section diagram of the circuit from point B to B′. An ESD plane 310 is placed on the back side of the PCB board. The LED devices 320 are connected in series. During normal operation, a supply current 325 flows through the LED devices 320 from point B to B′ via wire 340. VSD material 316 and a control gap 330 separate the ESD plane 310 from the wire 340 so that the supply current goes to the LED devices 320 during normal operation. A protruding terminal 315 is electrically connected to the ESD plane 310 and extends toward the wire 340. The protruding terminal 315 can be seen as a part of the ESD plane 310 and may or may not be made of the same material. An example of protruding terminal 315 is a metal via.

In one embodiment, VSD material 316 is placed underneath the circuit from point B to B′ and is shown as background from the top-view. In an ESD event, the VSD material 316 becomes electrically conductive and directs the surge current from wire 340 through the protruding terminal 315 to the ESD plane 310, which is located at the back side of the PCB board. This configuration enables current produced from an ESD event to be diverted at least partially away from the LED devices 320, so that potential ESD damage is avoided. By diverting at least a portion of the current away from the LED devices 320, the maximum voltage seen at the LED devices 320 may be reduced. Furthermore, through the VSD material 316 and protruding terminals 315, the heat generated by the LED devices 320 can be dissipated to the ESD plane 310 during the circuit's operation.

More specifically, in some embodiments, the ESD plane 310 may be used in junction with or be formed as a thermal pad. As in any variation, the ESD plane 310 may be formed, engraved, or etched to become a shape that increases surface area to enhance thermal conductivity. For example, the ESD plane 310 can be fin patterned, have vertical edges, or formed in concentric circles to facilitate its use as a heat sink.

In one or more embodiments, protruding terminal 315 is placed between the ESD plane 310 and the wire 340 to provide a shortest path to the ground for a surge current in ESD events. The protruding terminal 315 can be formed into any shape that results in reduced resistance to better direct the surge current to the ESD plane 310. For example, in one embodiment, the protruding terminal 315 is designed to form a circular shape on the end that is away from the ESD plane 310. The wire 340 can completely surround the protruding terminal 315. For example, the wire 340 can be circular or elliptical in shape to completely circumvent the protruding terminal 315. Among other benefits, such a configuration enables the protruding terminal 315 to have a relatively larger electrical conductivity area during ESD events (e.g., as compared to partially circumventing electrical wire), which allows a larger current flow for ESD surge current and can provide more protection to the LED devices 320.

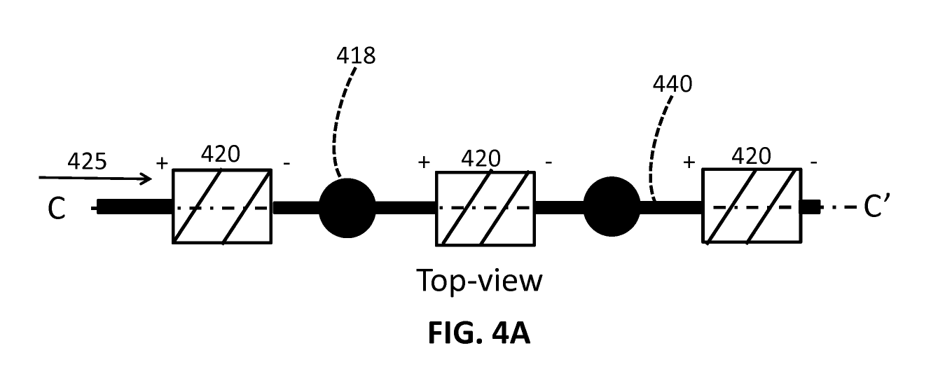

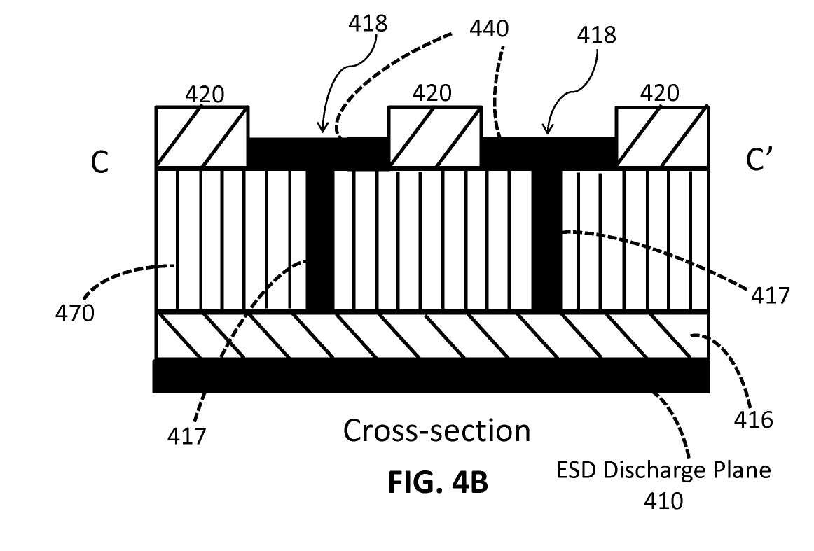

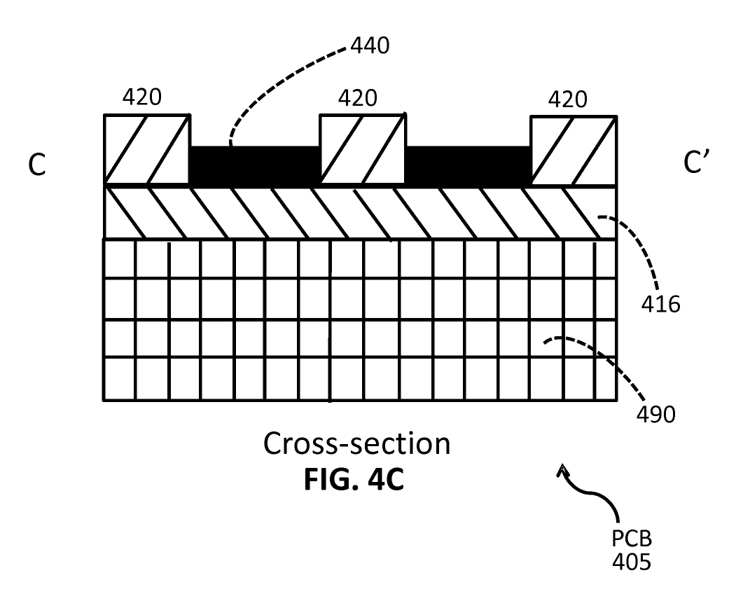

FIG. 4A and FIG. 4B further illustrate an embodiment of FIG. 1. Shown in FIG. 4A is a top-view diagram of a section of a circuit implemented on a double layer PCB board on electrical insulating substrate 470 from point C to C′. FIG. 4B is a cross-section diagram of the circuit from point C to C′. An ESD plane 410 is placed on the back side of the PCB board. The LED devices 420 here are connected in series. During normal operation, a supply current 425 flows through the LED devices 420 from point C to C′ via wire 440. In particular, an embodiment of FIG. 4A and FIG. 4B provides for a circuit design in which the VSD material 416 is embedded within a substrate, and provided as a layer that is vertically switched into the conductive state. A via 417 can be formed from conductive material such as metal, and be provided to extend vertically within the substrate layer to connect the VSD material 416 and the ESD plane 410. In this way, the VSD material 416 separates the ESD plane 410 from the wire 440 and the via 417 so that the supply current goes to the LED devices 420 during normal operation. During an ESD event, at least a portion of the VSD material 416 becomes electrically conductive, so as to vertically interconnect the via 417 and the ESD plane 410. The resulting electrical path directs the surge current from wire 440 through the metal via 417 to the ESD plane 410, which can be located at the back side of the PCB board. Since at least a portion of the current produced from an ESD event can be diverted away from the LED devices 420, resulting ESD damage can be avoided. Furthermore, through the VSD material 416 and protruding terminals, the heat generated by the LED devices 420 can be dissipated to the ESD plane 410 during the circuit's normal operation.

More specifically, in some embodiments, the ESD plane 410 may be used in junction with or be formed as a thermal pad. As in any variation, the ESD plane 410 may be formed, engraved, or etched to become a shape that increases surface area to enhance thermal conductivity. For example, the ESD plane 410 can be fin patterned, have vertically edges, or be formed in concentric circles to facilitate its use as a heat sink

In one or more embodiments, an electric contact 418 that connects the wire 440 and the metal via can be formed into any shape that results in reduced electrical resistance. In particular, an embodiment recognizes that increasing the area of the electrical contact 418 results in less electrical resistance being present to handle a surge current, which can be directed to the ESD plane 410. For example, in an embodiment shown, the electric contact 418 is designed to form a substantially circular or elliptical shape to increase the relative area of the electrical contact 418. The electric contact 418 can be seen as a part of the wire 440.

In another variation, FIG. 4C illustrates an embodiment in which a circuit with LED devices 420 is implemented on a PCB having a metal core. The PCB 405 includes a metal substrate 490 that can serve as an ESD plane. The VSD material 416 can be integrated with the metal substrate 490 of the PCB. For example, the VSD material 416 can be provided as a layer on one or both sides of the PCB.

Embodiments described herein recognize that the individual LEDs that comprise an array include different forward and reverse breakdown voltages. For example, across a given array, there is a maximum pulse forward current(I_{Fmax}_{_{—}}ₚᵤₗₛₑ) for a given LED that will damage the LED due to excessive heating. The maximum voltage across the LED during a forward biased surge event is V_{Fmax}_{_{—}}ₚᵤₗₛₑ. Therefore, V_{Fmax}_{_{—}}ₚᵤₗₛₑ can be greater than its operational voltage (V_{O}). Typically the reverse bias breakdown voltage V_{rbv} satisfies the relationship |V_{rbv}|>|V_{Fmax}_{_{—}}ₚᵤₗₛₑ|, but because of the finite source impedance of an ESD pulse and the strong LED non-linearity in the forward biased direction, typical LEDs may withstand a higher ESD pulse voltage in the forward biased regime than the reverse biased regime. To better protect an LED device, the VSD material may need to switch on at voltage values that are greater than the V_{RBV}.

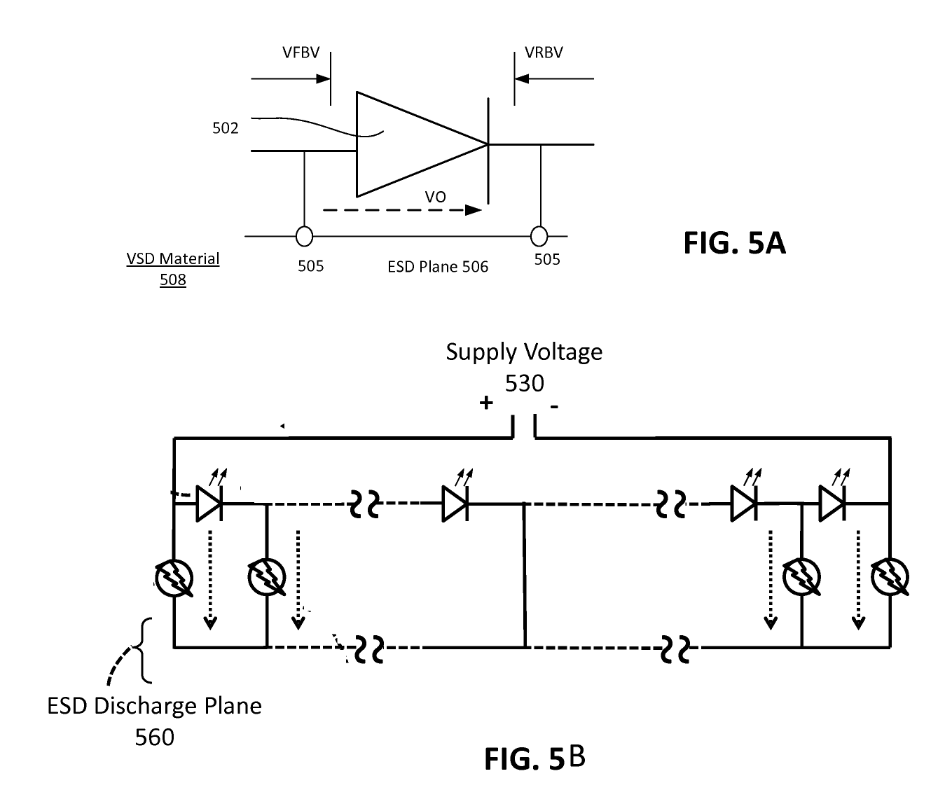

With reference to FIG. 5A, an LED 502 is shown that can be either a singular component, or part of an array of LEDs. The LED 502 can be characterized by given values for V_{FBV} and V_{RBV}, and operated at V_{O}. Additionally, the LED 502 can be extended to a voltage node 505 V_{node} provided at an ESD plane 506. The LED 502 and the ESD plane 506 may be connected to VSD material 508. The VSD material may be characterized by a turn-on voltage V_{CL} (e.g., clamping or trigger voltage).

The configuration shown for LED 502 in FIG. 5A can be replicated for an LED array, such as LED arrays in which the LEDs are aligned in series, in parallel or in combination thereof. Examples of such configurations for LED arrays are provided in greater detail below.

As an addition or an alternative embodiment, an ESD plane may have a configuration that, under normal operating conditions, keeps the plane's voltage fixed at a certain value. In FIG. 5B, an embodiment has the ESD plane 560 fixed at one-half of supply voltage 530, so that the voltage on the ESD plane 560 does not vary due to leakage current or other factors.

As in any one or more of the embodiments, the ESD plane 560 is made of electrically conductive material. Specific materials for use in ESD planes include copper, aluminum, gold, silver, or any other electrically conductive metal material common to the circuit design industry.

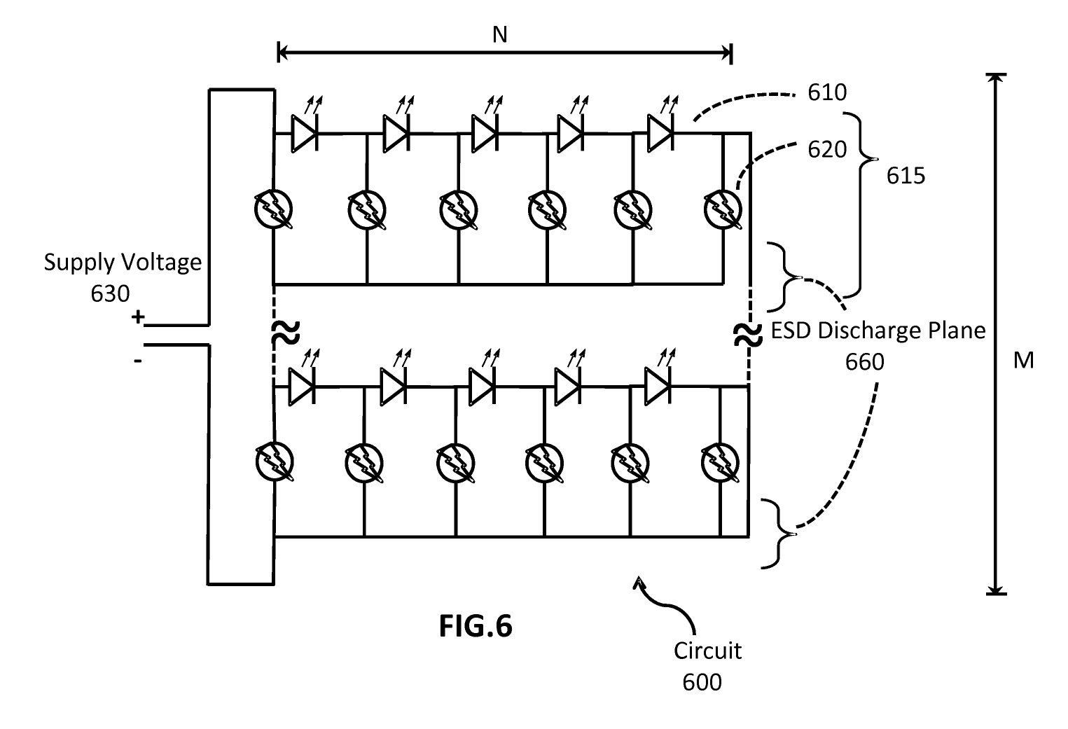

FIG. 6 is a schematic illustration of a circuit 600 with an array of LED devices 610, configured to incorporate VSD material 620, according to embodiments of the invention. The circuit 600 is shown to provide, under normal operating conditions, the LED devices 610 with a supply voltage 630. An ESD plane 660 is provided in electrical conjunction with the VSD material 620 as an outlet for the surge current which may occur in an ESD event. In an embodiment of FIG. 6, the plurality of the LED devices 610 are connected in series to form a cluster 615. Let N be the number of the LED devices 610 connected in said cluster 615, and M be the number of total clusters, so that M×N equals to the total number of LED devices 610 on the circuit 600. In a configuration in accordance with the schematic of FIG. 6, during normal operation, the voltage potential seen by the VSD material 620 within the cluster 615 is only N×V_{Forward} instead of N×M×V_{Forward}, as compared to a pure series configuration. In an ESD event, the maximum surge voltage exposed to any given LED device 610 is also reduced to approximately ±V_{CL}/N, which must be less than the maximum pulse breakdown voltage of the LED. The configuration can reduce the voltage potential placed on the VSD material during normal operating conditions, while minimizing the voltage potential placed on the LED devices when a surge voltage occurs.

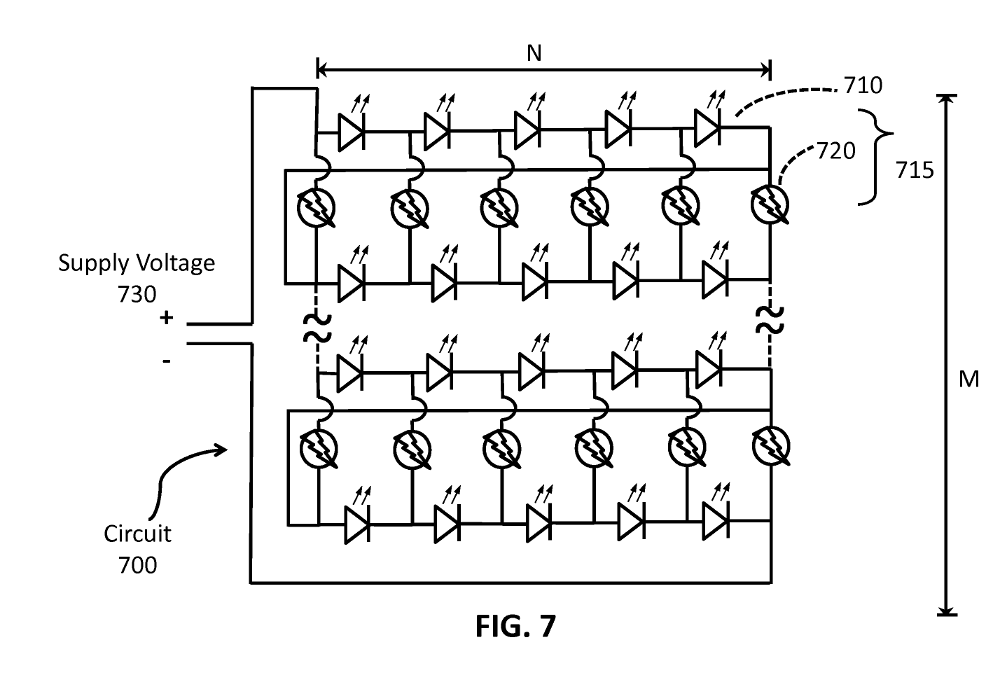

FIG. 7 is a diagram of a circuit 700 including an array of LED devices 710, configured to incorporate VSD material 720, according to another embodiment. The circuit 700 is shown to provide, under normal operating conditions, the LED devices 710 with a supply voltage 730. In an embodiment of FIG. 7, the plurality of the LED devices 710 are entirely connected in series. However, the circuit 700 is so configured that the VSD material 720 is divided into clusters 715. Let N be the number of the LED devices 710 placed on a cluster 715, and M be the number of total clusters, so that M×N roughly equals to the total number of LED devices 710 on the circuit 700. Within any given cluster 715, during normal operation, the voltage potential seen by the VSD material 720 within the cluster 715 is only N×V_{Forward} instead of N×M×V_{Forward}, as compared to a pure series configuration. In an ESD event, the maximum surge voltage exposed to any given LED device 710 is also reduced to approximately ±V_{CL}/N instead of ±V_{CL}, as compared to a pure series configuration. The configuration can reduce the voltage potential placed on the VSD material during normal operating conditions, while minimizing the voltage potential placed on the LED devices when a surge voltage occurs. Furthermore, a configuration such as shown FIG. 7 still enables a pure series connection, which is typically preferred in LED applications (e.g., as compared to the partial-parallel-partial-series configuration as illustrated in FIG. 6) because of the reduced likelihood of LED thermal runaway.

Although illustrative embodiments have been described in detail herein with reference to the accompanying drawings, variations to specific embodiments and details are encompassed herein. It is intended that the scope of the invention is defined by the following claims and their equivalents. Furthermore, it is contemplated that a particular feature described, either individually or as part of an embodiment, can be combined with other individually described features, or parts of other embodiments. Thus, absence of describing combinations should not preclude the inventor(s) from claiming rights to such combinations.

What is claimed is:

1. A circuit comprising:
an array of light emitting diodes (LEDs);
a layer of VSD material positioned to contact an input and an output of each LED in the array of LEDs, so as to protect each LED from both a forward surge and a reverse surge of voltage on the array of LEDs, the layer of VSD material switching into carrying current in response to either of the forward or reverse surge exceeding a characteristic voltage level (V_{CL}) of the VSD material.

2. The circuit of claim 1, further comprising an electrostatic discharge (ESD) plane that is connected to the layer of VSD material.

3. The circuit of claim 2, further comprising a via that interconnects the layer of VSD material to the array of LEDs.

4. The circuit of claim 3, wherein the layer of VSD material is vertically switched in order to electrically interconnect the ESD plane to individual LEDs in the array of LEDs.

5. The circuit of claim 2, wherein the layer of VSD material is arranged to protect individual LEDs in the array against a transient voltage that is greater than a reverse breakdown voltage of the individual LEDs in the array of LEDs.

6. The circuit of claim 2, wherein the ESD plane is embedded within a substrate on which the array of LEDs are provided.

7. The circuit of claim 1, further comprising a conductive element that interconnects at least some of the LEDs in the array of LEDs, and wherein the conductive element is positioned relative to the layer of VSD material to form a control gap with a grounding element that is provided on the layer of VSD material.

8. The circuit element of claim 7, wherein the conductive element only partially circumvents the grounding element.

9. The circuit element of claim 7, wherein the conductive element completely surrounds the grounding element.

10. The circuit element of claim 2, wherein the ESD plane is shaped to operate as a heat sink for the array of LEDs.

11. The circuit of claim 2, wherein a voltage (V_{node}) at a node of the ESD plane is provided so that V_{CL} is larger than an operating voltage Vₒ of an individual LED in the array of LEDs.

12. The circuit of claim 2, wherein the array of LEDs include a first set of LEDs that are arranged in series.

13. The circuit of claim 5, wherein the array of LEDs include a second set of LEDs that are arranged in series, and wherein the first set of LEDs and the second set of LEDs are collectively arranged in parallel.

14. The circuit of claim 1, wherein the layer of VSD material is formed from a varistor.

15. A device comprising:
plurality of light emitting diodes (LEDs);
a layer of VSD material positioned to contact an input and an output of each LED in the plurality of LEDs, so as to protect each LED from both a forward surge and a reverse surge of voltage on the array of LEDs, the layer of VSD material switching into carrying current in response to either of the forward or reverse surge exceeding a characteristic voltage level (V_{CL}) of the VSD material.

16. The device of claim 15, wherein the device is a light emitting diode (LED) lighting module.

17. The device of claim 15, wherein the device is a light emitting diode (LED) display module.
